(19) United States
(12) Patent Application Publication
(10) Pub. No.: US 2015/0284845 A1
(43) Pub. Date: Oct. 8, 2015

(54) FILM-FORMING APPARATUS

(71) Applicant: KABUSHIKI KAISHA WATANABE SHOKO, Tokyo (JP)

(72) Inventors: Masayuki Toda, Fukushima (JP); Masaru Umeda, Tokyo (JP)

(73) Assignee: KABUSHIKI KAISHA WATANABE SHOKO, Tokyo (JP)

(21) Appl. No.: 14/405,870

(22) PCT Filed: Jun. 5, 2013
(86) PCT No.: PCT/JP2013/065551

§ 371 Date: May 18, 2015

(30) Foreign Application Priority Data
Jun. 5, 2012 (JP) 2012-128284

(51) Int. Cl. C23C 16/44; C23C 16/46; C23C 16/455

(52) U.S. Cl. CPC C23C 16/4412; C23C 16/455; C23C 16/46

(57) ABSTRACT

A film forming apparatus, in which vaporized gas of liquid raw material not adequately vaporized in a vaporizer is completely vaporized passing through a pipe for feeding vaporized gas of liquid raw material arranged between the vaporizer and an film forming chamber, and applies in the film forming chamber, is provided. The apparatus includes a supplying system of liquid raw material for film forming; a vaporizer, which vaporizes the liquid raw material by mixing with carrier gas; a film forming chamber, which flows the vaporized gas of liquid raw material from the vaporizer on a base plate, and forms film; and a pipe feeding vaporized gas of liquid raw material, which supplies gas from the vaporizer to the film forming chamber. The pipe for feeding vaporized gas of liquid raw material has a spiral shape, and the axis as the spiral shape is arranged vertical direction to a floor plane.

### TECHNICAL FIELD

The present invention relates a film forming apparatus and a vaporizer installation method, specifically a film forming apparatus characterized in that a pipe for feeding vaporized gas of liquid raw material, which is connected from a vaporizer to film forming chamber, is formed spiral.

### BACKGROUND ART

Conventionally, in a film forming apparatus forming a film on a surface of a semiconductor wafer by using a CVD apparatus etc. including a MOCVD apparatus, a technology, which supplies carrier gas including liquid material for film forming to a vaporizer and vaporizes raw material in the vaporizer, is known.

In this vaporizer, a heater is arranged on the circumference of the heater and a pipe, which supplies carrier gas in the heater, and raw material is vaporized by its heat.

Cited reference 1 shows a technology, in which liquid raw material is introduced to carrier gas, the refined liquid raw material is dispersed in the carrier gas (Below, carrier gas with dispersed liquid raw material is called as gaseous raw material), this gaseous raw material is introduced to a vaporizer for the raw material etc. to be vaporized, the gaseous raw material with vaporized raw material etc. is introduced in a film forming chamber by a pipe for feeding vaporized gas of liquid raw material, and film forming executed in the film forming chamber.

In this time, only solvent is vaporized. In order to prevent generation of blocking at an exit and other problems, cooling means is provided at the exit. Also, in order to disperse the liquid raw material in the carrier gas as smaller particles, flow velocity from 50 to 340 m/sec for the carrier gas is used as adequate condition.

But, when film forming is executed with above technology, ripples often occur on the surface of the film. And, particles exist in the film or on the surface of the film. Also, there is a case that composition of the film is deviated from target composition. Also, there is a case that carbon content becomes large.

FIG. 4 shows a conventional film forming apparatus. In FIG. 4, a film forming apparatus has a structure that a vaporizer 30b is arranged on the upper side of a film forming chamber 40b, and the vaporizer 30b and the film forming chamber 40b are connected with a raw material vaporized gas feed pipe 50d.

FIG. 5 shows a conventional vaporizer. The conventional vaporizer is formed with a dispersion unit body 8, a connection unit 23, and a vaporization unit 22, which are sequentially connected to the downward.

### PRIOR ART DOCUMENTS

### Patent Literature

Patent Literature 1: WO02/058141

### SUMMARY OF THE INVENTION

### Problems that the Invention is to Solve

The conventional film forming apparatus has a structure that the vaporizer is arranged on the upper side of the film forming chamber, and the vaporizer and the film forming chamber is connected with the linear pipe for feeding vaporized gas of liquid raw material.

### Problems

The conventional film forming apparatus has a case that the liquid raw material gas, which is not completely vaporized in the vaporizer, is introduced to the film forming chamber through the pipe for feeding vaporized gas of liquid raw material.

The problem of the present invention is to provide a film forming apparatus, in which vaporized gas of liquid raw material, that is not completely vaporized in a vaporizer, is completely vaporized while passing through a pipe for feeding vaporized gas of liquid raw material arranged between the vaporizer and a film forming chamber, and applies in the film forming chamber.

### Means for Solving the Problems

The present invention 1 is a film forming apparatus comprised of a supplying system of liquid raw material for film forming; a vaporizer, which vaporizes the liquid raw material by mixing with carrier gas; a film forming chamber, which flows the vaporized gas of liquid raw material from the vaporizer on a base plate, and forms film; and a pipe for feeding vaporized gas of liquid raw material, which supplies gas from the vaporizer to the film forming chamber; wherein the pipe for feeding vaporized gas of liquid raw material is formed into a spiral shape.

The present invention 2 is the film forming apparatus according to the present invention 1, wherein the axis of the pipe for feeding vaporized gas of liquid raw material as the spiral shape is arranged vertical direction to a floor plane.

The present invention 3 is the film forming apparatus according to the present invention 1, wherein the axis of the pipe for feeding vaporized gas of liquid raw material as the spiral shape is arranged horizontal direction to a floor plane.

The present invention 4 is the film forming apparatus according to the present invention 1, wherein the axis of the pipe for feeding vaporized gas of liquid raw material as the spiral shape is comprised of directions vertically and horizontally arranged for a floor plane. The present invention 5 is the film forming apparatus according to any one of the present invention 1 to 4, wherein the pipe for feeding vaporized gas of liquid raw material is heated at a temperature 20% to 30% higher than the boiling point of the vaporized gas of liquid raw material.

### Effects of the Invention

According to the film forming apparatus of the present invention 1, the gaseous raw material, which is not completely vaporized in the vaporizer, can be completely vaporized while passing through the pipe for feeding vaporized gas of liquid raw material arranged between the vaporizer and the film forming chamber, and supplied in the film forming chamber.

According to the film forming apparatus of the present invention 2, air flow of the vaporized gas of liquid raw material occurs secondary flow by centrifugal force, which vertically works to the axis as the spiral shape, in the pipe for feeding vaporized gas of liquid raw material. This flow goes toward the centrifugal force direction in the section of the feed pipe, goes back against to the centrifugal force direction at the boundary surface of the fluid, and again goes toward the centrifugal force direction. Then, because strong fluid mixed action is occurred in the fluid, progression of smoother vaporization is expected.

According to the film forming apparatus of the present invention 3, air flow of the vaporized gas of liquid raw material occurs secondary flow by centrifugal force, which vertically works to the axis as the spiral shape, in the pipe for feeding vaporized gas of liquid raw material. This flow goes toward the centrifugal force direction in the section of the feed pipe, goes back against to the centrifugal force direction at the boundary surface of the fluid, and again goes toward the centrifugal force direction. Then, because strong fluid mixed action is occurred in the fluid, progression of smoother vaporization is expected.

According to the film forming apparatus of the present invention 4, air flow of the vaporized gas of liquid raw material occurs secondary flow by centrifugal force, which vertically works to the axis as the spiral shape, in the pipe for feeding vaporized gas of liquid raw material. This flow goes toward the centrifugal force direction in the section of the feed pipe, goes back against to the centrifugal force direction at the boundary surface of the fluid, and again goes toward the centrifugal force direction. Then, because strong fluid mixed action is occurred in the fluid, progression of smoother vaporization is expected.

According to the film forming apparatus of the present invention 5, because the pipe for feeding vaporized gas of liquid raw material is heated at a temperature 20% to 30% higher than the boiling point of the vaporized gas of liquid raw material, vaporization is definitely progressed.

According to the present invention, the film forming apparatus, in which vaporized gas of liquid raw material, that is not completely vaporized, is completely vaporized while passing through the pipe for feeding vaporized gas of liquid raw material arranged between the vaporizer and the film forming chamber, and applies in the film forming chamber, can be provided.

### BRIEF DESCRIPTION OF DRAWINGS

FIG. 1 is an illustration of the film forming apparatus according to Embodiment 1 of the present invention;

FIG. 2 is an illustration of the film forming apparatus according to Embodiment 2 of the present invention;

FIG. 3 is an illustration of the film forming apparatus according to Embodiment 3 of the present invention;

FIG. 4 is an illustration of a conventional film forming apparatus; and

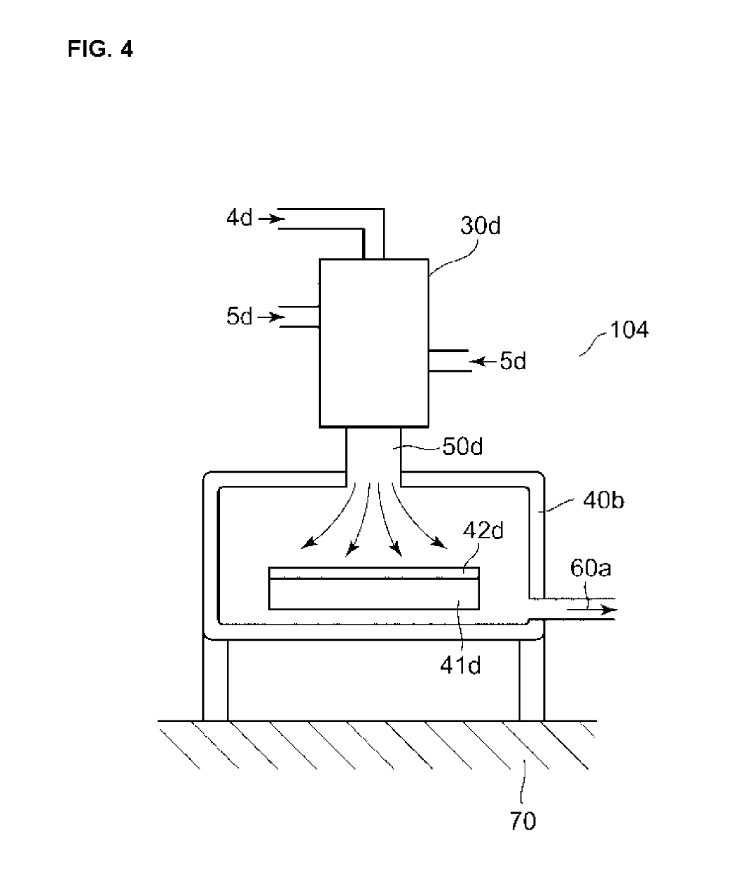

FIG. 5 is a cross section of the vaporizer used for the film forming apparatus.

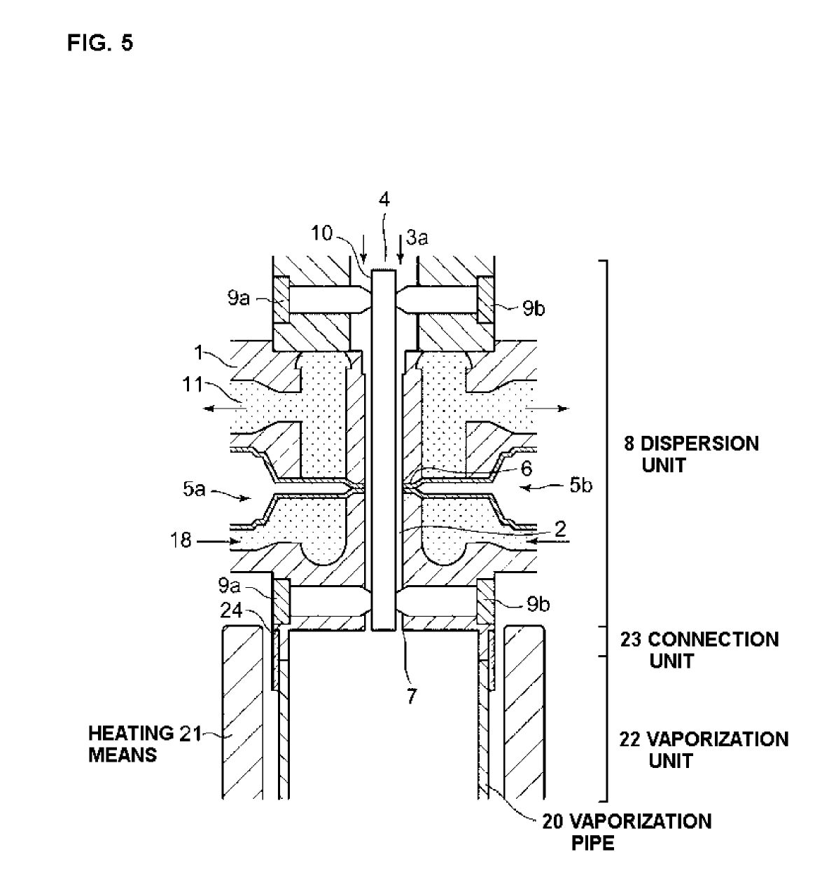

### DESCRIPTION OF REFERENCE NUMBERS AND SIGNS

1: Dispersion unit body

2: Gas passage

3a: Carrier gas

4, 4a, 4b, 4c, 4d: Carrier gas inlet

5a 5b, 5c, 5d: First raw material solution for film forming

6a, 6b, 6c, 6d: Second raw material solution for film forming

6: Raw material supply hole

7: Gas outlet

9a, 9b: Vis

10: Center rod

16: Stopper

17: Notch

18: Cooling water

20: Vaporization pipe

21: Heating means

22: Vaporization unit

23: Connection unit

8: Dispersion unit

24: Joint

30a, 30b, 30c, 30d: Vaporizer

40a, 40b, 40c, 40d: Film forming chamber

41a, 41b, 41c, 41d: Substrate

42a, 42b, 42c, 42d: Base plate

50a, 50b, 50c, 50d: Pipe for feeding vaporized gas of liquid raw material

60a 60b: Exhaust pipe

70: Floor

101, 102, 103, 104: Film forming apparatus

### DESCRIPTION OF EMBODIMENTS

A film forming apparatus of the present application is comprised of a supplying system of liquid raw material for film forming; a vaporizer, which vaporizes the liquid raw material by mixing with carrier gas; a film forming chamber, which flows the vaporized gas of liquid raw material from the vaporizer on a base plate, and forms film; and a pipe for feeding vaporized gas of liquid raw material, which supplies gas from the vaporizer to the film forming chamber; wherein the pipe for feeding vaporized gas of liquid raw material is formed into a spiral shape.

Here, the spiral shape of the pipe for feeding vaporized gas of liquid raw material has several cases.

For example, there are a case, in which the axis of the pipe for feeding vaporized gas of liquid raw material as the spiral shape is arranged vertical direction to a floor plane, and a case, in which the axis is arranged horizontal direction to a floor plane.

Also, there is a case, in which the above axis is composed of directions vertically and horizontally arranged for a floor plane. Direction of the axis as the spiral shape is not restricted the above cases. For Example, the axis may be arranged obliquely i.e. having angle to the vertical direction to a floor plane.

As the pipe for feeding vaporized gas of liquid raw material, stainless steel material is mainly used. But, it is not restricted.

### Embodiments

Embodiments of the film forming apparatus of the present invention will be described hereafter.

### Embodiment 1

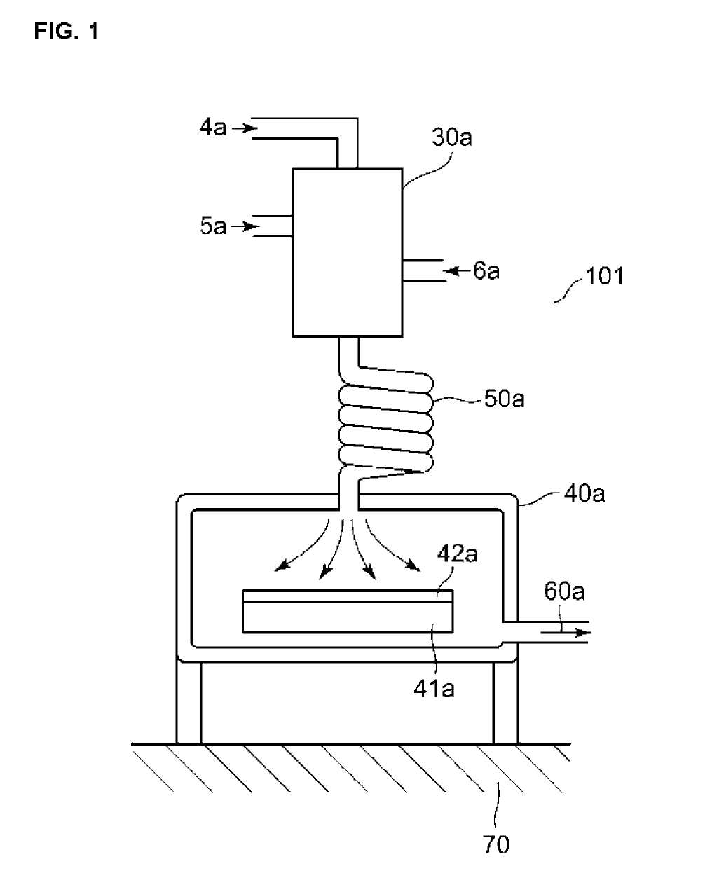

FIG. 1 is an illustration of the film forming apparatus 101 according to Embodiment of the present invention. The film forming apparatus 101 is comprised of the supplying system of liquid raw material for film forming (Not shown); the vaporizer 30a, which vaporizes the liquid raw material by mixing with carrier gas; the film forming chamber 40a, which flows the liquid raw material vaporizes gas from the vaporizer on the base plate, and forms film; and the pipe 50a for feeding vaporized gas of liquid raw material, which supplies gas from the vaporizer to the film forming chamber 40a.

Here, the axis of the pipe 50a for feeding vaporized gas of liquid raw material as the spiral shape is arranged vertical direction to a floor plane.

Outside diameter of the pipe was, for example, set to 19 mm, and length was set to 2170 mm (Upstream side 200 mm of straight-line part of the spiral part, and downstream side 100 mm of straight-line part are respectively counted). Inside diameter of the spiral part of the pipe was 100 mm φ, and outside diameter was 138 mm φ. Revolution number of the spiral was set more than 5. And, in the case of pipe whose outside diameter is 34 mm (1 inch size pipe), length was set to 2410 mm (Upstream side 200 mm of straight-line part of the spiral part, and downstream side 100 mm of straight-line part are respectively counted). Inside diameter of the spiral part of the pipe was 100 mm φ, and outside diameter was 168 mm φ. Revolution number of the spiral was set more than 5.

By constructing as described above, air flow of the vaporized gas of liquid raw material occurs secondary flow by centrifugal force, which vertically works to the axis as the spiral shape. This flow goes toward the centrifugal force direction in the section of the feed pipe, goes back against to the centrifugal force direction at the boundary surface of the fluid, and again goes toward the centrifugal force direction. Then, because strong fluid mixed action is occurred in the fluid, progression of smoother vaporization is expected. Namely, the gaseous raw material, which is not adequately vaporized in the vaporizer 30a arranged at the previous stage, is certainly vaporized.

### Embodiment 2

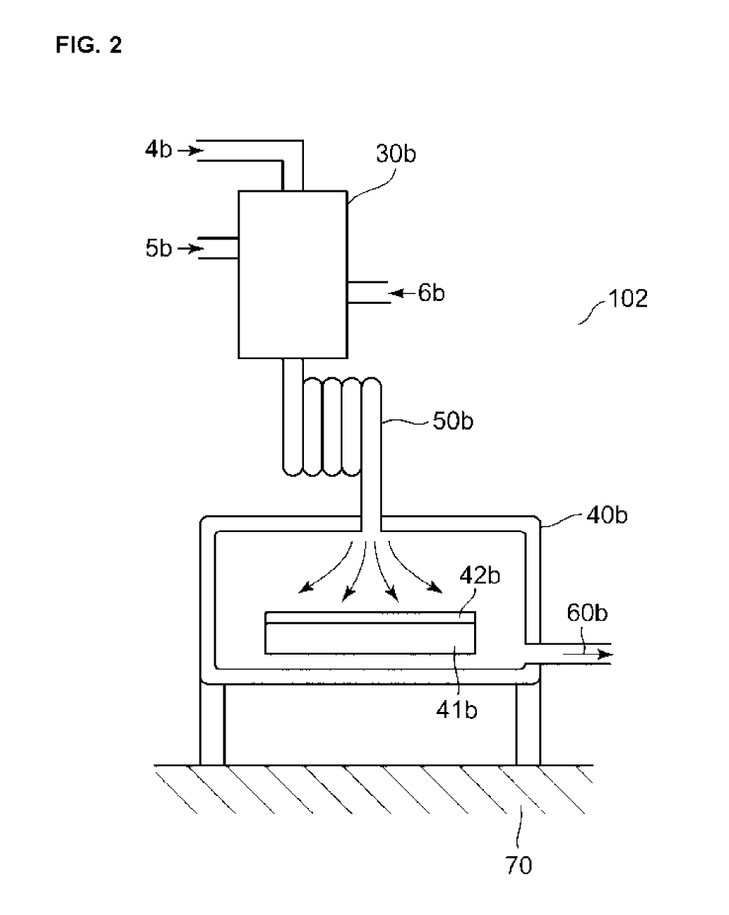

FIG. 2 is an illustration of the film forming apparatus 102 according to Embodiment of the present invention.

The film forming apparatus 102 is comprised of the supplying system of liquid raw material for film forming (Not shown); the vaporizer 30b, which vaporizes the liquid raw material by mixing with carrier gas; the film forming chamber 40b, which flows the liquid raw material vaporizes gas from the vaporizer on the base plate, and forms film; and the pipe 50b for feeding vaporized gas of liquid raw material, which supplies gas from the vaporizer to the film forming chamber 40b.

Here, the axis of the pipe 50b for feeding vaporized gas of liquid raw material as the spiral shape is arranged horizontal direction to a floor plane.

Outside diameter of the pipe was, for example, set to 19 mm, and length was set to 2170 mm (Upstream side 200 mm of straight-line part of the spiral part, and downstream side 100 mm of straight-line part are respectively counted). Inside diameter of the spiral part of the pipe was 100 mm φ, and outside diameter was 138 mm φ. Revolution number of the spiral was set more than 5. And, in the case of pipe whose outside diameter is 34 mm (1 inch size pipe), length was set to 2410 mm (Upstream side 200 mm of straight-line part of the spiral part, and downstream side 100 mm of straight-line part are respectively counted). Inside diameter of the spiral part of the pipe was 100 mm φ, and outside diameter was 168 mm φ. Revolution number of the spiral was set more than 5.

By constructing as described above, air flow of the vaporized gas of liquid raw material occurs secondary flow by centrifugal force, which vertically works to the axis as the spiral shape. This flow goes toward the centrifugal force direction in the section of the feed pipe, goes back against to the centrifugal force direction at the boundary surface of the fluid, and again goes toward the centrifugal force direction. Then, because strong fluid mixed action is occurred in the fluid, progression of smoother vaporization is expected. Namely, the gaseous raw material, which is not adequately vaporized in the vaporizer 30b arranged at the previous stage, is certainly vaporized.

### Embodiment 3

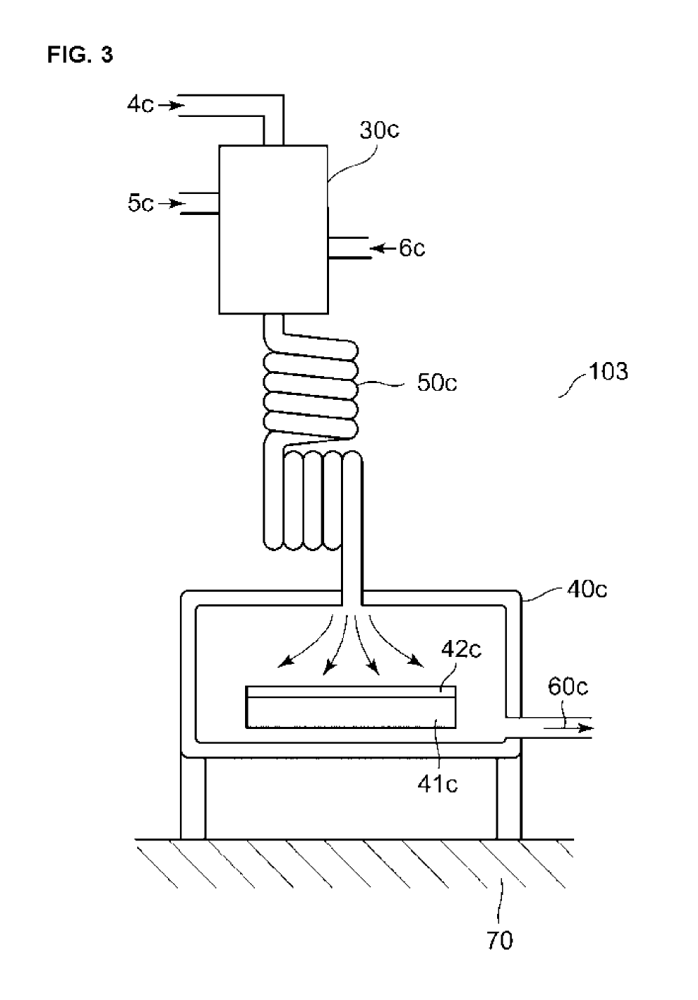

FIG. 3 is an illustration of the film forming apparatus 103 according to Embodiment of the present invention.

The film forming apparatus 103 is comprised of the supplying system of liquid raw material for film forming (Not shown); the vaporizer 30c, which vaporizes the liquid raw material by mixing with carrier gas; the film forming chamber 40c, which flows the liquid raw material vaporizes gas from the vaporizer on the base plate, and forms film; and the pipe 50c for feeding vaporized gas of liquid raw material, which supplies gas from the vaporizer to the film forming chamber 40c.

Here, the axis of the pipe 50c for feeding vaporized gas of liquid raw material as the spiral shape is composed of vertical direction and horizontal direction to a floor plane.

Outside diameter of the pipe was, for example, set to 19 mm, and length was set to 4040 mm (Upstream side 200 mm of straight-line part of the first spiral part, and downstream side 100 mm of straight-line part of the second spiral part are respectively counted). Inside diameter of the spiral part of the pipe was 100 mm φ, and outside diameter was 138 mm φ. Revolution number of the spiral was set more than 5. And, in the case of pipe whose outside diameter is 34 mm (1 inch size pipe), length was set to 2410 mm (Upstream side 200 mm of straight-line part of the first spiral part, and downstream side 100 mm of straight-line part of the second spiral part are respectively counted). Inside diameter of the spiral part of the pipe was 100 mm φ, and outside diameter was 168 mm φ. Revolution number of the spiral was set more than 10.

By constructing as described above, air flow of vaporized gas of liquid raw material occurs secondary flow by centrifugal force, which vertically works to the axis as the spiral shape. This flow goes toward the centrifugal force direction in the section of the feed pipe, goes back against to the centrifugal force direction at the boundary surface of the fluid, and again goes toward the centrifugal force direction. Then, because strong fluid mixed action is occurred in the fluid, progression of smoother vaporization is expected. Namely, the gaseous raw material, which is not adequately vaporized in the vaporizer 30c arranged at the previous stage, is certainly vaporized.

### INDUSTRIAL APPLICABILITY

According to the film forming apparatus of the present invention, it becomes possible to completely vaporize the liquid raw material, quality of film forming by semiconductor production apparatus can be improved.

1. A film forming apparatus comprised of a supplying system of liquid raw material for film forming; a vaporizer, which vaporizes the liquid raw material by mixing with carrier gas; film forming chamber, which flows vaporized gas of liquid raw material from the vaporizer on a base plate, and forms film; and a pipe for feeding vaporized gas of liquid raw material, which supplies gas from the vaporizer to the film forming chamber; wherein the pipe for feeding vaporized gas of liquid raw material is formed into a spiral shape.

2. The film forming apparatus according to claim 1, wherein the axis of the pipe for feeding vaporized gas of liquid raw material as the spiral shape is arranged vertical direction to a floor plane.

3. The film forming apparatus according to claim 1, wherein the axis of the pipe for feeding vaporized gas of liquid raw material as the spiral shape is arranged horizontal direction to a floor plane.

4. The film forming apparatus according to claim 1, wherein the axis of the pipe for feeding vaporized gas of liquid raw material as the spiral shape is comprised of directions vertically and horizontally arranged for a floor plane.

5. The film forming apparatus according to claim 1, wherein the pipe for feeding vaporized gas of liquid raw material is heated at a temperature 20% to 30% higher than the boiling point of the vaporized gas of liquid raw material.

6. The film forming apparatus according to claim 2, wherein the pipe for feeding vaporized gas of liquid raw material is heated at a temperature 20% to 30% higher than the boiling point of the vaporized gas of liquid raw material.

7. The film forming apparatus according to claim 3, wherein the pipe for feeding vaporized gas of liquid raw material is heated at a temperature 20% to 30% higher than the boiling point of the vaporized gas of liquid raw material.

8. The film forming apparatus according to claim 4, wherein the pipe for feeding vaporized gas of liquid raw material is heated at a temperature 20% to 30% higher than the boiling point of the vaporized gas of liquid raw material.
